(19) United States
(12) Patent Application Publication
(10) Pub. No.: US 2010/0044084 A1
(43) Pub. Date: Feb. 25, 2010

(54) Printed circuit board and method of manufacturing the same

(75) Inventors: Dong Gyu LEE, Suwon-si (KR); Seon Jae MUN, Suwon-si (KR); Jin Won CHOI, Seoul (KR); Tae Joon CHUNG, Seoul (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/289,273

(22) Filed: Oct. 23, 2008

(30) Foreign Application Priority Data
Aug. 19, 2008 (KR) 10-2008-0080986

(51) Int. Cl. H05K 1/11; H05K 1/09; H05K 3/00

(52) U.S. Cl. 174/257; 174/267; 29/843

(57) ABSTRACT

Provided is a printed circuit board (PCB) including a substrate that has a pad formed thereon; solder resist that is disposed on the substrate so as to expose the pad; a post that is disposed on the post; a surface-treatment layer that is disposed on the post; and a bump that is disposed on the surface-treatment layer.

### CROSS-REFERENCE TO RELATED APPLICATIONS

This application claims the benefit of Korean Patent Application No. 10-2008-0080986 filed with the Korean Intellectual Property Office on Aug. 19, 2008, the disclosure of which is incorporated herein by reference.

### BACKGROUND OF THE INVENTION

1. Field of the Invention

The present invention relates to a printed circuit board (PCB) and a method of manufacturing the same.

2. Description of the Related Art

Recently, as electronic products are reduced in size and weight, semiconductor parts provided in the electronic products have been reduced in size and weight. To cope with such a technical trend, an interest in a packaging technique for mounting semiconductor elements on a PCB for package is increasing.

Among a plurality of packaging techniques, flip-chip packaging is to directly connect a conductive pad of a semiconductor chip to a conductive pad of a PCB through a conductive solder bump. Accordingly, since the flip-chip packaging can be applied to a PCB having a pad with a minute pitch, it is possible to manufacture a semiconductor package with an integrated circuit configuration. Further, in the semiconductor package manufactured by the flip-chip packaging, a signal transmission distance can be reduced, compared with that of a semiconductor package manufactured by another packaging technique. Therefore, it is possible to increase the speed of the semiconductor chip.

Since the flip-chip packaging has such an advantage, it is being widely studied and commonly used. However, the flip-chip packaging has a limit in coping with such a technical trend that a circuit pattern and a pad of the PCB are gradually miniaturized. That is, as the circuit pattern and the pad are miniaturized, the pitch of the solder bump should be reduced. At this time, as the pitch of the solder bump is reduced, the height of the bump, i.e., a stand-off is reduced. When the stand-off is reduced, excessive stress generated by a difference in heat expansion rate between a substrate and a semiconductor element may be applied to the bump. The excessive stress may destroy the bump, and thus the bonding reliability of the bump may be degraded.

To prevent the degradation of the reliability which occurs when the bump pitch is reduced, a metal post with a predetermined height is formed, and a plating and reflow process is performed on the metal post so as to form a solder bump on the metal post.

However, since an inter-metallic compound is formed between the metal post and the solder bump during the reflow process, the coupling force between the metal post and the solder bump is reduced. Here, when the inter-metallic compound is formed to have a proper thickness of less than 3 ηm, it serves to increase the coupling force between two metals. However, when the thickness of the inter-metallic compound excessively increases, the coupling force between two metals decreases. In particular, when the metal post form of Cu is directly contacted with the solder, it is much more difficult to control the thickness of the inter-metallic compound.

Further, before the solder is formed, the metal post may be exposed to the outside so as to be oxidized. The oxidization of the metal post may degrade the wettability of the solder for the post. Accordingly, the contact reliability between the PCB and the semiconductor chip is degraded.

Therefore, although the bump with a minute pitch can be formed by providing the metal post on the package substrate for the flip-chip packaging, the contact reliability between the post and the bump is degraded due to the inter-metallic compound and the oxidization of the post.

### SUMMARY OF THE INVENTION

An advantage of the present invention is that it provides a PCB in which a surface-treatment layer is provided between a post and a bump, thereby enhancing contact reliability between the post and the bump, and a method of manufacturing the same.

Additional aspect and advantages of the present general inventive concept will be set forth in part in the description which follows and, in part, will be obvious from the description, or may be learned by practice of the general inventive concept.

According to an aspect of the invention, a PCB comprises a substrate having a pad; a solder resist disposed on the substrate and exposing the pad; a post disposed on the post; a surface-treatment layer disposed on the post; and a bump disposed on the surface-treatment layer.

The surface-treatment layer may contain a Ni—Sn-based inter-metallic compound.

The PCB may further comprise an interface layer disposed between the pad and the post.

The bump may be formed on a top surface of the post, the bump having a cap shape.

A portion of the post may be protruded from the top surface of the solder resist.

According to another aspect of the invention, a method of manufacturing a PCB comprises providing a substrate having a pad formed thereon; forming a solder resist on the substrate, the solder resist exposing the pad; forming a post on the exposed pad; forming a preliminary surface-treatment layer on the post; and forming solder on the preliminary surface-treatment layer and performing a reflow process, thereby forming a surface-treatment layer and a bump.

The preliminary surface-treatment layer may be formed of any one of Au/Ni, Au/Ni alloy, Ni, Ni alloy, Ad/Ni, Pd/Ni alloy, Au/Pd/Ni, and Au/Pu/Ni alloy.

An interface layer may be formed between the pad and the post.

The method may further comprise forming a resist pattern on the solder resist, between the forming of the post and the forming of the preliminary surface-treatment layer.

The solder may be flattened with respect to the top surface of the resist pattern.

The resist pattern may be removed after the reflow process is performed on the solder.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view of a PCB according to an embodiment of the present invention;

FIGS. 2 to 11 are process diagrams for explaining a method of manufacturing a PCB according to a second embodiment of the invention;

FIG. 12 is a diagram showing a method of forming solder; and

FIGS. 13 and 14 are diagrams showing other methods of forming solder.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures. In the drawings, the thicknesses of layers and regions are exaggerated for clarity.

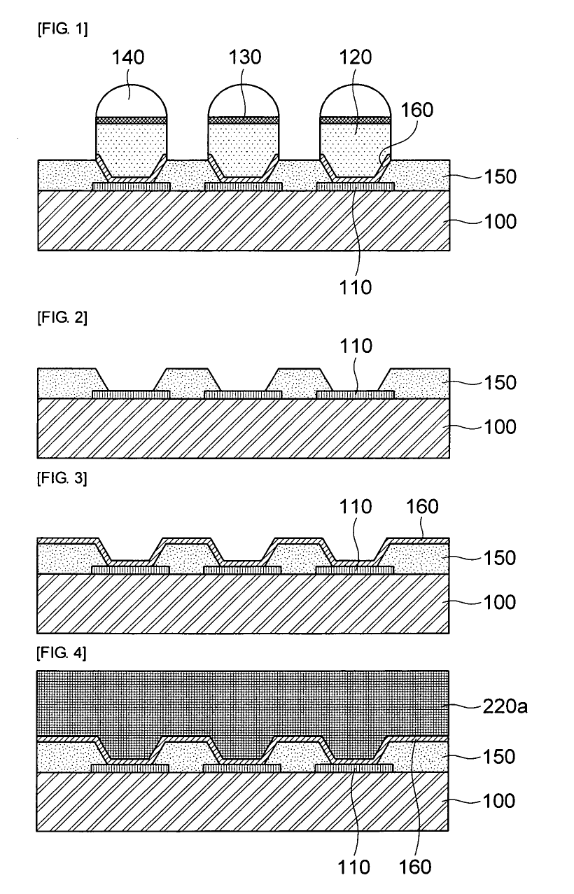

FIG. 1 is a cross-sectional view of a PCB according to an embodiment of the present invention.

Referring to FIG. 1, a pad 110 is disposed on a substrate 100. The substrate 100 may be a semiconductor substrate or circuit board, and is not limited thereto. For example, the substrate 100 may be a multi-layer circuit board including circuit layers and insulating layers which are alternately laminated.

The substrate 100 is electrically connected through the pad to an external part, for example, a semiconductor chip. Although not shown, a circuit pattern may be disposed on the substrate 100, in addition to the pad 110.

A solder resist 150 is disposed on the substrate 100 including the pad 110. The solder resist 150 includes an opening through which the pad 110 is exposed, in order for the electric connection between the pad 110 and the external part. In this embodiment, a material forming the solder resist 150 and the circuit is not limited, and any material may be used as long as it is typically used in the art.

A post 120 is disposed on the pad 110 exposed through the solder resist 150. The post 120 is formed in such a shape that a portion of the post 120 protrudes from the top surface of the solder resist 150. Due to the post 120, a distance between the PCB and the external part, i.e. a stand-off may be increased. Accordingly, a bump 140 which will be described below can relax excessive stress caused by a difference in thermal expansion rate between the PCB and the semiconductor chip. Therefore, the bonding reliability of the bump 140 increases. Further, as the post 120 is exposed to the outside, the heat generated from the substrate 100 can be more effectively distributed.

The post 120 may be formed of a conductive material. For the conductive material, Cu, Ni, Sn, and Au may be taken as an example.

Although not shown, an interface layer may be provided between the pad 110 and the post 120. The interface layer serves to prevent the oxidization of the pad 110. The interface layer may be formed of Ni or Ni/Au.

A surface-treatment layer 130 is disposed on the post 120. The surface-treatment layer 130 serves to increase an interface bonding force between the post 120 and the bump 40. The surface-treatment layer 130 may be formed to have a thickness of less than 3 ηm. When the thickness of the surface-treatment layer 130 is set to more than 3 ηm, the interface bonding force between the bump 140 and the post 120 may decrease. The surface-treatment layer 130 may be formed of an inter-metallic compound. The inter-metallic compound may be a Ni—Sn-based inter-metallic compound which is formed to have a uniform thickness of less than 1 ηm. Accordingly, the surface-treatment layer 130 is disposed on the post 120, thereby making it possible to increase the interface bonding force between the post 120 and the bump 140. Further, since the surface-treatment layer 130 can prevent the oxidization of the post 120, the wettability of the solder forming the bump 40 can be enhanced.

The bump 40 is disposed on the surface-treatment layer 130. The bump 140 may contain Sn-based metal, in order to form a Ni—Si-based inter-metallic compound together with the material forming the surface-treatment layer 130. For example, the bump 40 may contain any one of Sn, Sn—Ag, and Sn—Ag—Cu. The bump 140 is disposed on only the top surface of the post 120. That is, the bump 140 may be formed in a cap shape so as to be disposed on the post 120.

In this embodiment, as the surface-treatment layer 130 is provided on the post 120, it is possible to enhance the contact reliability between the post 120 and the bump 140.

Reference numeral 160 represents a seed layer for forming the post 120.

FIGS. 2 to 11 are process diagrams for explaining a method of manufacturing a PCB according to a second embodiment of the invention.

First, as shown in FIG. 2, a substrate 100 having a pad 110 formed thereon is prepared. The substrate 100 may be a semiconductor substrate or circuit board.

Solder resist 150 is formed on the substrate 100 such that the pad 110 is partially exposed. The solder resist 150 may be formed by applying photosensitive resin and then performing a photolithography and developing process on the photosensitive resin film. The photosensitive resin may be formed of epoxy resin and acrylic resin.

Further, an interface layer may be formed on the substrate 100 including the pad 110 and the solder resist 150. The interface layer serves to prevent the oxidization of the pad 110. The interface layer may be formed of Ni or Ni/Au, and may be formed by an electroless plating method. In this embodiment, it has been described that the interface layer is formed. However, when a pickling process for removing an oxide film on the pad 110 is performed before the post 120 is formed on the pad 110, the interface layer may be omitted.

Referring to FIG. 3, a seed layer 160 is formed on the substrate 100 including the pad 110 and the solder resist 150. The seed layer 160 may be formed of Cu, and may be formed through an electroless plating method.

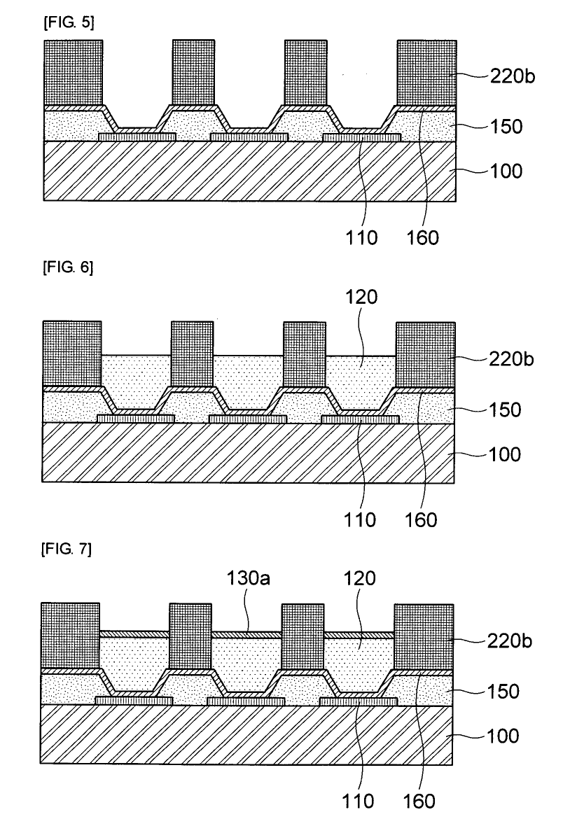

Referring to FIG. 4, a photosensitive film 220a is formed on the substrate 100 including the seed layer 160. Then, a photolithography and developing process is performed on the photosensitive film 220a so as to form a resist pattern 220b which exposes the pad 110, as shown in FIG. 5. That is, the resist pattern 220b is disposed on the solder resist 150.

Referring to FIG. 6, a post 120 is formed on the pad 110 exposed by the resist pattern 220b and the solder resist 150. The post 120 may be formed by an electroplating method. The post 120 may be formed of Cu, Ni, Sn, or Au.

Referring to FIG. 7, a preliminary surface-treatment layer 130a for forming a surface-treatment layer 130 is formed on the post 120. The preliminary surface-treatment layer 130a may be formed of Au/Ni, Au/Ni alloy, Ni, Ni alloy, Ad/Ni, Pd/Ni alloy, Au/Pd/Ni, or Au/Pu/Ni alloy. The preliminary surface-treatment layer 130a may be formed by an electroplating or electroless plating method.

The preliminary surface-treatment layer 130a serves to increase the wettability of solder forming the bump 140 and to prevent the oxidization of the post 120.

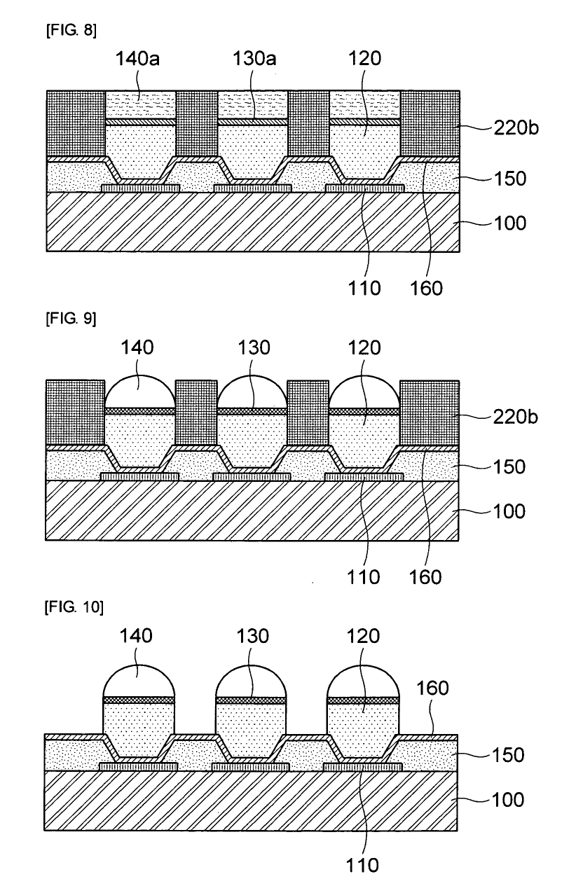

Referring to FIG. 8, solder 140a is formed on the preliminary surface-treatment layer 130a. The solder 140a fills up an opening of the resist pattern 220b so as to be flattened. That is, the top surface of the solder 140a is aligned with the top surface of the resist pattern 220b. Therefore, when a plurality of bumps 140 is to be formed, a height difference among the bumps 140 can be reduced.

A method of flattening the solder 140a will be described in detail below.

Referring to FIG. 9, a bump 140 is formed on the post 120 by performing a reflow process on the solder 140a. During the reflow process, a surface-treatment layer 130 is formed, containing an inter-metallic compound between Ni of the preliminary surface-treatment layer 130a and Sn of the solder 140a as a main component. That is, the surface-treatment layer 130 may be a Ni—Sn-based inter-metallic compound. The surface-treatment layer 130 is formed to have a thickness of less than 1 ηm. Accordingly, the surface-treatment layer 130 serves to enhance an interface bonding force between the post 120 and the bump 140, thereby enhancing the bonding reliability between the post 120 and the bump 140.

The resist pattern 220b can prevent the solder 140a from permeating into a side surface of the post 120 during the reflow process. Therefore, since the permeation of the solder 140a into the side surface of the post 120 does not need to be considered, it is possible to minimize an amount of the solder 140a to be used. Further, the resist pattern 220b can prevent an inter-metallic compound from being formed on the side surface of the post 120.

Referring to FIG. 10, the resist pattern 220b is removed after the reflow process is performed. Accordingly, the post 120 is formed in such a shape that a portion thereof protrudes from the top surface of the solder resist 150.

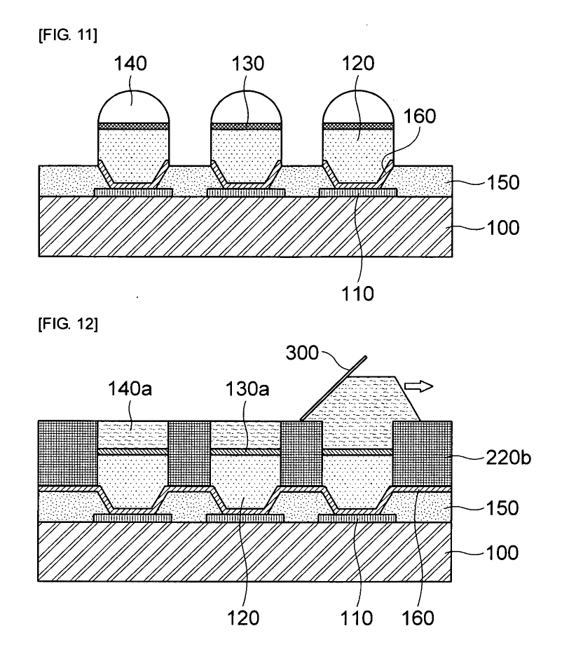

Referring to FIG. 11, after the resist pattern 220b is removed, the seed layer 160 disposed under the resist pattern 220b is removed. Then, as shown in FIG. 12, it is possible to manufacture a PCB which can be applied to the flip-chip packaging.

According to the method of manufacturing a PCB, the surface-treatment layer 130 is formed between the post 120 and the bump 140, thereby making it possible to enhance the bonding reliability between the post 120 and the bump 140.

Further, as the resist pattern 220b is removed after the reflow process, it is possible to minimize an amount of the solder 140a to be used.

Further, as the solder 140a is flattened with respect to the resist pattern 220b, a thickness difference between the bumps 140 can be reduced.

Hereinafter, a method of flattening the solder will be described in detail with reference to FIGS. 12 to 14.

FIG. 12 is a diagram showing a method of forming solder.

Referring to FIG. 12, solder paste 140a is applied on the substrate 100, on which the resist pattern 220b with an opening is formed, by a squeegee printing device having a squeegee 300. In this case, while the squeegee 300 is moved on the substrate 100, the opening can be filled with the solder paste 140 such that the solder paste 140 is flattened.

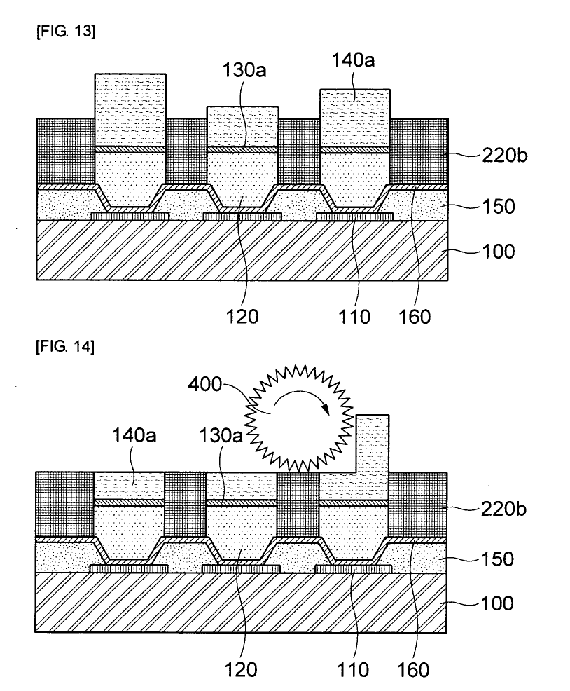

FIGS. 13 and 14 are diagrams showing other methods of forming solder.

Referring to FIG. 13, solder 140a is formed by performing a plating process on the substrate 100 on which the resist pattern 220b with an opening is formed. At this time, the solder 140a can be flattened while the opening is filled with the solder 140a. However, when the plating process is controlled, the process may be difficult to perform. Therefore, the solder 140a is formed so as to protrude from the surface of the resist pattern 220b while the opening is filled with the solder 140a. Thereafter, the protruding portion of the solder 140a is removed through a mechanical grinding process, for example, a grinding process using a buff 400 such that the solder 140a can be flattened. Further, when the height of the bump should be controlled, the surface of the resist pattern 220b may be further ground.

In this embodiment, as the solder 140a is flattened, a height difference among the bumps formed of the solder can be reduced.

According to the present invention, since the PCB includes the surface-treatment layer which can increase the interface bonding force between the post and the bump, the contact reliability between the post and the bump can be enhanced.

Further, the oxidization of the post can be prevented by the surface-treatment layer, and the wettability of the solder forming the bump with respect to the post can be enhanced.

Further, as the resist pattern is removed after the reflow process of the solder, the solder can be prevented from permeating into the side surface of the post, which makes it possible to minimize an amount of the solder to be used. Furthermore, as the amount of the solder to be used is easily controlled, it is possible to prevent a bridge connecting the adjacent bumps from being formed.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A printed circuit board (PCB) comprising:
a substrate having a pad;;
a solder resist disposed on the substrate and exposing the pad
a post disposed on the post;
a surface-treatment layer disposed on the post; and
a bump disposed on the surface-treatment layer.

2. The PCB according to claim 1, wherein the surface-treatment layer contains a Ni—Sn-based inter-metallic compound.

3. The PCB according to claim 1 further comprising:
an interface layer disposed between the pad and the post.

4. The PCB according to claim 1, wherein the bump is formed on a top surface of the post, the bump having a cap shape.

5. The PCB according to claim 1, wherein a portion of the post is protruded from the top surface of the solder resist.

6. A method of manufacturing a PCB, comprising:
providing a substrate having a pad;
forming a solder resist on the substrate, the solder resist exposing the pad;
forming a post on the exposed pad;
forming a preliminary surface-treatment layer on the post; and
forming a solder on the preliminary surface-treatment layer and performing a reflow process, thereby forming a surface-treatment layer and a bump.

7. The method according to claim 6, wherein the preliminary surface-treatment layer is formed of any one of Au/Ni, Au/Ni alloy, Ni, Ni alloy, Ad/Ni, Pd/Ni alloy, Au/Pd/Ni, and Au/Pu/Ni alloy.

8. The method according to claim 6, wherein an interface layer is formed between the pad and the post.

9. The method according to claim 6 further comprising:
forming a resist pattern on the solder resist, between the forming of the post and the forming of the preliminary surface-treatment layer.

10. The method according to claim 9, wherein the solder is flattened with respect to the top surface of the resist pattern.

11. The method according to claim 9, wherein the resist pattern is removed after the reflow process is performed on the solder.
